(19) United States
(12) Patent Application Publication
(10) Pub. No.: US 2007/0092757 A1
(43) Pub. Date: Apr. 26, 2007

(54) Phosphorescent organic light-emitting diodes

(75) Inventor: Tswen-Hsin Liu, Jhudong Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/371,570

(22) Filed: Mar. 9, 2006

(30) Foreign Application Priority Data
Oct. 26, 2005 (TW) 94137440

(51) Int. Cl. H01L 51/54

(52) U.S. Cl. 428/690; 428/917; 313/504; 313/506; 257/89; 257/E51.022

(57) ABSTRACT

A phosphorescent OLED has a light emitting layer which includes a phosphorescent host material, an exiton blocking material, and a phosphorescent dopant. The invention obviates the use of a hole blocking layer while substantially preventing hole diffusion to the electron transport layer.

### BACKGROUND OF THE INVENTION

1. Field of the Invention

The invention relates to organic light-emitting devices, and in particular relates to phosphorescent light-emitting devices and its application.

2. Description of the Related Art

Organic light-emitting diodes (OLED) are based on organic molecules. The quantum yield of phosphorescent materials (theoretical yield 100%) is higher than that of conventional fluorescent materials (theoretical yield 25%), and therefore the phosphorescent materials may retain luminance for a long time after terminating excitation. Phosphorescent organic light-emitting devices, however, must overcome two major obstacles. At first, synthesis of phosphorescent molecules, especially blue and green light-emitting phosphorescent molecules, is more difficult than conventional fluorescent organic molecules. Second, when the excitation energy diffuses from the light-emitting layer to other layers, it induces color impurity and light elimination, and therefore a hole blocking layer (HBL) between a light-emitting layer and an electron transport layer is necessary, as disclosed in U.S. Pat. Nos. 6,097,147 and 6,784,016. A full color panel requires R, G, B pixels arranged in side by side manner, but the research and development of blue phosphorescent pixels are seriously delayed compared to red and green phosphorescent pixels. Integration of blue fluorescent pixels into phosphorescent pixels is therefore necessary. A challenge to process integration is that the manufacture of phosphorescent pixels requires an additional evaporation chamber for HBL, which complicates the process, and increases the cost and time.

To eliminate the problems caused from HBL, SEL, Inc. replaces the P-type host light-emitting materials with N-type host light-emitting materials (disclosed in U.S. Pat. No. 6,734,457). The N-type host light-emitting materials can be used without HBL, because they possess hole blocking ability. With N-type host light-emitting materials, however, process integration with pixels using conventional P-type host light-emitting materials is difficult.

### BRIEF SUMMARY OF INVENTION

To solve the above problems concerning HBL, the invention provides a phosphorescent organic light-emitting device comprising a cathode, an anode, a light-emitting layer disposed between the cathode and the anode; the light-emitting layer comprises a phosphorescent host material, an exiton blocking material, and a phosphorescent dopant.

The invention also provides a display apparatus comprising a phosphorescent OLED as described above, and a driving circuit couples to the phosphorescent OLED for driving the phosphorescent OLED.

The invention further provides a full color display apparatus comprising a red phosphorescent OLED, a green phosphorescent OLED, and a blue fluorescent OLED; wherein the phosphorescent OLED has a light-emitting layer containing an exiton blocking material.

A detailed description is given in the following with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a cross section of Examples 1-3 of the present invention;

FIG. 2 shows a cross section of Comparative Example 1;

FIG. 3 shows a cross section of Comparative example 2;

FIG. 4 shows a schematic view showing luminance yield versus current density of Example 1, Comparative example 1, and Comparative example 2; and

FIG. 5 is a diagram showing a display apparatus of the present invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

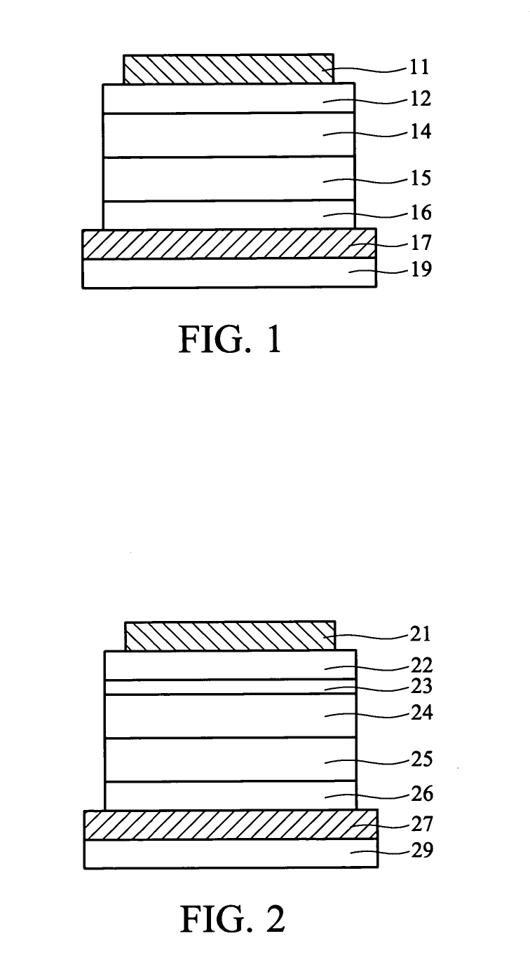

As shown in FIG. 1, the invention provides a phosphorescent OLED comprising a cathode 11, an anode 17, a light-emitting layer 14 disposed between the cathode 11 and the anode 17. First, the anode 17 is formed on a substrate 19, and then washed by wet etching or plasma cleaning. After washing the light-emitting layer 14 is formed on the anode 17 by evaporation or spin-on coating, and the cathode 11 is coated on the light-emitting layer 14 in vacuum.

At least one of the cathode 11 and the anode 17 is transparent, and the other may comprise metal, metal alloy, transparent metal oxide, or a combination of these materials. Suitable metals for present invention include Al, Ca, Ag, Ni, Cr, Ti, or Mg. Examples of the metal alloy comprise indium tin oxide (ITO), indium zinc oxide (IZO), cadmium tin oxide (CTO), metallized azocompound, zinc oxide (ZnO), indium nitride (InN), or stannum dioxide (SnO₂).

In the invention, the light-emitting layer 14 comprises a phosphorescent host material, an exiton blocking material, and a phosphorescent dopant. The phosphorescent host materials may be N-type or P-type, and preferably carbazole-based materials comprising 4,4′-bis(9-carbaazoyl)-2,2′-biphenyl (CBP) or derivatives thereof. The phosphorescent dopant includes, but is not limited to, complexes of Os, Ir, Pt, Eu, or Ru. The Ir complex with N-containing heterocyclic ligands has higher quantum yield and preferred light emission band. The phosphorescent dopant has a concentration region from about 5 to about 20%. The exiton blocking materials include, but are not limited to, bathocuproin (BCP), aluminum(III) bis(2-methyl-8-quinolinato)-4-phenylphenolate (BAlq), 1,2,4-Triazoles (TAZ), 1,3,5-tris(N-phenyl-benzimidazol-2-yl)benzene (TPBI), 4,7-diphenyl-1,10-phenanthroline (BPhen), or derivatives thereof. The phosphorescent host material and the exiton blocking material have a volume ratio from 10:90 to 90:10, and the light-emitting layer has a preferable thickness from 200 to 600 angstroms.

The invention may further comprise a hole injection layer 16 (HIL) or a hole transporting layer 15 (HTL) diposed between the anode 17 and the light-emitting layer 14, and an electron injection layer (EIL, not shown) or an electron transporting layer 12 (ETL) disposed between the cathode 11 and light-emitting layer 14. The HIL may comprise fluorinated polymer, porphyrin derivatives, or P-doped amine derivatives. Suitable porphyrin derivatives may include metallophthalocyanine derivatives, such as copper phthalocyanine.

The HTL 15 comprises amino polymer, such as N,N′-bis(1-naphyl)-N,N′-diphenyl-1,1′-biphenyl-4,4′-diamine (NPB), N,N′-diphenyl-N,N′-bis(3-methylphenyl)-1,1′-biphenyl)-4,4′-diamine (TPD), 2T-NATA, or derivatives there of. The HTL 15 has a thickness from 50 to 5000 angstroms.

Representation EIL may be alkali halide, alkaline-earth halide, alkali oxide, or alkali carbonate, such as LiF, CsF, NaF CaF₂, Li₂O, Cs₂O, Na₂O, Li₂CO₃, Cs₂CO₃, or Na₂CO₃. The EIL has a thickness from 5 to 50 angstroms.

The OLED structure as described above is formed as follows: an anode 17 is formed on a substrate 19, and then washed by wet etching or plasma cleaning. After washing the multi layer OLED is formed by evaporation or spin-on coating: the HIL 16 is formed on the anode 17, the HTL 15 is formed on the HIL 16, the light-emitting layer 14 is formed on the HTL 15, the ETL 12 is formed on the light-emitting layer 14, and the EIL is formed on the ETL 12. At last, the cathode 11 is coated on the light-emitting layer 14 in vacuum.

Note that because the present devices do not require a hole blocking layer between the light emitting layer 14 and the ETL 12, thereby simplifying the process while improving quantum yield.

The present invention provides a display apparatus comprising the above OLED. Applications of the display apparatus include, but are not limited to, EL display apparatuses, digital cameras, laptop computers, portable media player devices, mobile phones, video camcorders, portable data terminals, digital video CD/VCD/DVD players, and projectors.

The above display apparatuses comprise a driving circuit that couples to an OLED for driving the OLED. The driving circuit can be an active matrix type or a passive matrix type.

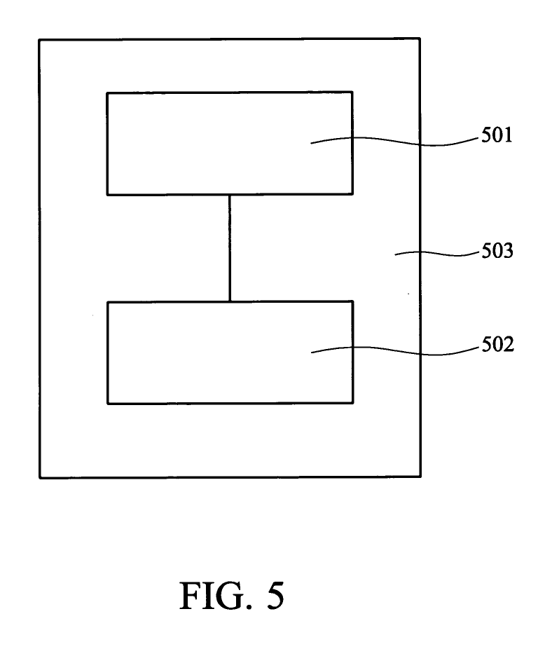

FIG. 5 shows the display apparatus of the invention. The apparatus 503 comprises at least one phosphorescent OLED 501 and a driving circuit 505, wherein the driving circuit 505 coupled to a phosphorescent OLED 501 for driving the phosphorescent OLED 501.

The invention further provides a full color display apparatus comprising the red and green phosphorescent OLED described above and a blue fluorescent OLED. The apparatus integrates the matured blue fluorescent OLEDs with the phosphorescent OLEDs of the present invention, which obviates the need of extra evaporation chambers for the HBL.

### DEVICE EXAMPLES

### Example 1

FIG. 1 shows a cross section view of Examples 1-3.

Anode 17: indium tin oxide (ITO) of about 700 angstroms on a glass substrate 19;

HIL 16: 4,4′,4″-tri(N-(2-naphthyl)-N-aniline)-triphenyl amine (2T-NATA) of about 150 nm;

HTL 15: N,N′-di-1-naphthyl-N,N′-diphenyl-1,1′-biphenyl-1,1′-biphenyl-4,4′-diamine (NPB) of about 600 angstroms;

light-emitting layer 14: CBP (phosphorescent host material) and BAlq (exiton blocking material) had a volume ratio of 70:30, and a red phosphorescent dopant had 15% volume ratio of the light-emitting layer; and the light-emitting layer had a thickness of 550 angstroms;

ETL 12: Alq₃ of 300 nm;

EIL (not shown): LiF of 10 angstroms; and

cathode 11: Al of 200 nm.

### Example 2

Anode 17: indium tin oxide (ITO) of about 700 angstroms on a glass substrate 19;

HIL 16: 2T-NATA of about 150 nm;

HTL 15: NPB of about 600 angstroms;

light-emitting layer 14: CBP (phosphorescent host material) and BAlq (exiton blocking material) had a volume ratio of 70:30, and a green phosphorescent dopant had 8% volume ratio of the light-emitting layer; and the light-emitting layer had a thickness of 550 angstroms;

ETL 12: Alq₃ of 300 nm;

EIL (not shown): LiF of 10 angstroms; and

cathode 11: Al of 200 nm.

### Example 3

Anode 17: indium tin oxide (ITO) of about 700 angstroms on a glass substrate 19;

HIL 16: 2T-NATA of about 150 nm:

HTL 15: NPB of about 600 angstroms;

light-emitting layer 14: CBP (phosphorescent host material) and BAlq (exiton blocking material) had a volume ratio of 70:30, and a blue phosphorescent dopant had 12% volume ratio of the light-emitting layer; and the light-emitting layer had a thickness of 550 angstroms;

ETL 12: Alq₃ of 300 nm;

EIL (not shown): LiF of 10 angstroms; and

cathode 11: Al of 200 nm.

### Comparative Example 1

FIG. 2 shows a cross section view of Comparative Example 1 comprising a hole blocking layer.

Anode 27: indium tin oxide (ITO) of about 700 angstroms on a glass substrate 29;

HIL 26: 2T-NATA of about 150 nm;

HTL 25: NPB of about 600 angstroms;

light-emitting layer 24: CBP (phosphorescent host material) and BAlq (exiton blocking material) had a volume ratio of 70:30, and a red phosphorescent dopant (as the dopant used in Example 1) had 15% volume ratio of the light-emitting layer; and the light-emitting layer had a thickness of 400 angstroms;

HBL 23: BAlq of 150 angstroms;

ETL 22: Alq₃ of 300 mm;

EIL (not shown): LiF of 10 angstroms; and

cathode 21: Al of 200 nm.

### Comparative Example 2

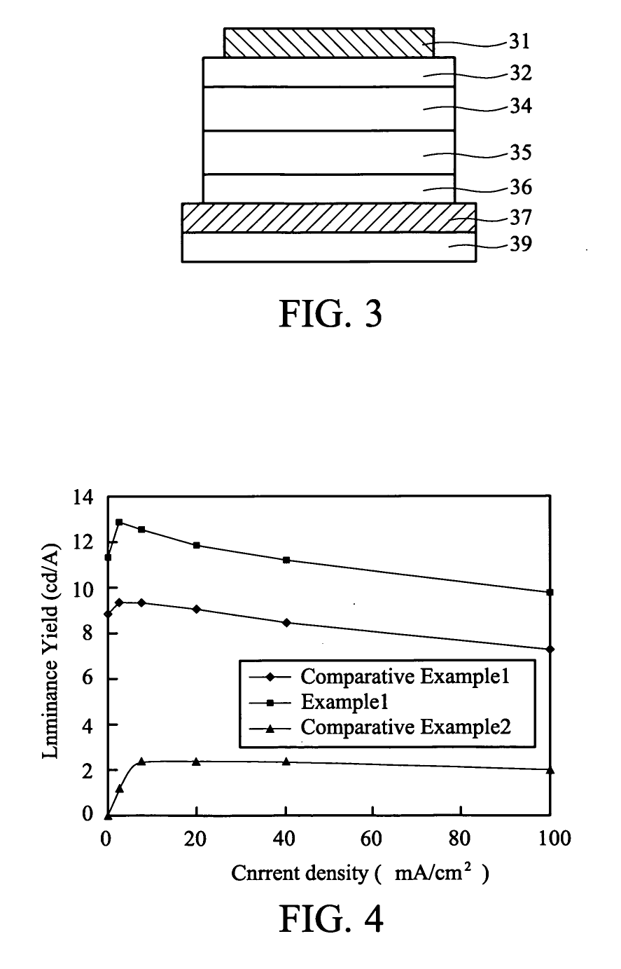

FIG. 3 shows a cross section view of Comparative Example 2 without any exiton blocking material.

Anode 37: indium tin oxide (ITO) of about 700 angstroms on a glass substrate 39;

HIL 36: 2T-NATA of about 150 nm;

HTL 35: NPB of about 600 angstroms;

light-emitting layer 34: CBP (phosphorescent host material) and BAlq (exiton blocking material) had a volume ratio of 70:30, and a red phosphorescent dopant (as the dopant used in Example 1) had 15% volume ratio of the light-emitting layer; and the light-emitting layer had a thickness of 400 angstroms;

ETL 32: Alq₃ of 300 nm;

EIL (not shown): LiF of 10 angstroms; and

cathode 31: Al of 200 nm.

Example 1 had a light-emitting layer comprising an exiton blocking material, Comparative Example 1 was a conventional OLED device containing a HBL, and Comparative Example 2 did not have any exiton blocking element. According to FIG. 4, the luminance yield of Example 1 was better than that of Comparative Examples 1 and 2.

The device of the invention (e.g. Example 1) is not only higher than the conventional device with the HBL (e.g. Comparative Example 1) in luminance yield, but also simplifying the process in manufacturing a phosphorescent OLED.

Compared with conventional arts without the HBL (such as SEL using N-type phosphorescent host materials), the present invention simply mixes the phosphorescent host material and the exiton blocking material in an appropriate ratio and the exitons can be sufficiently blocked. It does not require synthesizing a phosphorescent material that has both exiton blocking ability and light-emitting property. Accordingly, the invention provides a simple and more integratable process, and enjoys wider selection of materials.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phosphorescent organic light-emitting device, comprising:
a cathode;
an anode; and
a light-emitting layer disposed between the cathode and the anode, wherein the light-emitting layer comprises a phosphorescent host material, an exiton blocking material, and a phosphorescent dopant.

2. The device as claimed in claim 1, further comprising a hole transporting layer disposed between the anode and the light-emitting layer, and an electron transporting layer disposed between the cathode and the light-emitting layer.

3. The device as claimed in claim 2, further comprising a hole injecting layer disposed between the anode and the hole transporting layer, and an electron injecting layer disposed between the cathode and the electron transporting layer.

4. The device as claimed in claim 1, wherein the phosphorescent host material is N-type or P-type.

5. The device as claimed in claim 1, wherein the phosphorescent host material comprises a carbazole-based compound.

6. The device as claimed in claim 1, wherein the exiton blocking material comprises bathocuproin (BCP), aluminum(III) bis(2-methyl-8-quinolinato)-4-phenylphenolate (BAlq), 1,2,4-Triazoles (TAZ), 1,3,5-tris(N-phenyl-benzimidazol-2-yl)benzene (TPBI), 4,7-diphenyl-1,10-phenanthroline (BPhen), or derivatives thereof.

7. The device as claimed in claim 1, wherein the light-emitting layer has a thickness ranging from about 200 angstroms to about 600 angstroms.

8. The device as claimed in claim 1, wherein the phosphorescent dopant has a concentration ranging from about 5% to about 20% by volume.

9. The device as claimed in claim 1, wherein the phosphorescent dopant and the light-emitting layer have a volume ratio from about 10:90 to about 90:10.

10. The device as claimed in claim 1, wherein the phosphorescent dopant comprises a red phosphorescent dopant, a green phosphorescent dopant, or a blue phosphorescent dopant.

11. The device as claimed in claim 1, wherein at least one of the cathode and the anode comprises a transparent electrode.

12. The device as claimed in claim 11, wherein at least one of the cathode and the anode comprises metal, alloy, transparent metal oxide, or mixture thereof.

13. The device as claimed in claim 11, wherein the cathode and the anode are made of substantially the same material.

14. The device as claimed in claim 11, wherein the cathode and the anode are made of substantially different materials.

15. A display apparatus, comprising:
a phosphorescent organic light-emitting device of claim 1; and
a driving circuit coupled to the device for driving the device.

16. The apparatus as claimed in claim 15, the driving circuit is active matrix type.

17. The apparatus as claimed in claim 15, the driving circuit is passive matrix type.

18. A full color display apparatus, comprising:
a phosphorescent organic light-emitting device of claim 1 emitting red light;
a phosphorescent organic light-emitting device of claim 1 emitting green light; and
a blue fluorescent organic light-emitting device.
